(19) United States
(12) Patent Application Publication
(10) Pub. No.: US 2024/0064638 A1
(43) Pub. Date: Feb. 22, 2024

(54) METHOD FOR COMMUNICATING BETWEEN A PORTABLE TRANSMISSION DEVICE AND AN ELECTRONIC CONTROL UNIT OF A MOTOR VEHICLE

(71) Applicant: Continental Automotive Technologies GmbH, Hannover (DE)

(72) Inventors: Stéphane Billy, Toulouse (FR); Jérôme Lee, Toulouse (FR); Romain Poussier, Toulouse (FR)

(21) Appl. No.: 18/271,717

(22) PCT Filed: Jan. 7, 2022
(86) PCT No.: PCT/EP2022/050262

§ 371 Date: Jul. 11, 2023

(30) Foreign Application Priority Data
Jan. 13, 2021 (FR) 2100296

(51) Int. Cl. H04W 52/02

(52) U.S. Cl. CPC H04W 52/0229

(57) ABSTRACT

A method for communicating between a portable transmission device and an electronic control unit of a motor vehicle. The method includes transmission, by the transmission device, of a plurality of wake-up signals over a plurality of consecutive time intervals referred to as “reference” time intervals. The duration of each reference time interval being equal to the duration of a supply period and each reference time interval being divided into a series of consecutive time slots. At least one wake-up signal of the plurality of wake-up signals being transmitted in each reference time interval, in a time slot that is different from the time slots of the other wake-up signals of the plurality of wake-up signals, and such that the sum of the transmission time intervals of each of the wake-up signals of the plurality of wake-up signals is at least equal to the supply period.

### CROSS REFERENCE TO RELATED APPLICATIONS

This application is the U.S. National Phase Application of PCT International Application No. PCT/EP2022/050262, filed Jan. 7, 2022, which claims priority to French Patent Application No. 2100296, filed Jan. 13, 2021, the contents of such applications being incorporated by reference herein.

### FIELD OF THE INVENTION

The present invention relates to the automotive field and more particularly to a method and a system for communicating between a portable transmission device and a vehicle. The invention applies in particular to the unlocking of the opening elements of a motor vehicle.

### BACKGROUND OF THE INVENTION

It is known practice today to remotely unlock the opening elements of a vehicle using an electronic key. To this end, when the user presses a button on the key, the key sends a signal referred to as a “wake-up” signal, called WUP for Wake-Up Pattern, in the RF frequency band.

In order to receive the signal, the vehicle comprises an electronic control unit coupled to a receiving antenna. To save energy, however, it is known practice to program the electronic control unit so that it periodically activates and deactivates itself in order to supply power to the receiving antenna during a time interval referred to as a “reception” time interval.

In existing solutions, in order to ensure that the receiving antenna detects the wake-up signal, that is to say receives at least one bit of the wake-up signal, the wake-up signal is transmitted for a length of time that is long enough to cover at least one reception time interval. For example, when the reception time interval is 1 ms every 39 ms (i.e. the receiving antenna is turned on for 1 ms for 38 ms of waking), the wake-up signal is transmitted for 40 ms in order to ensure that the data of the same wake-up signal are received during two consecutive reception time intervals. The wake-up signal can be transmitted twice consecutively in order to strengthen the wake-up protocol.

With this solution, periodically waking up the electronic control unit results in an average power consumption of up to 1 mA over a wake-up period, which can be up to 40% of the overall consumption of the electronic control unit in the waking mode of the electronic control unit.

In order to reduce this consumption, one solution involves extending the wake-up period of the electronic control unit, that is to say increasing the length of time between two consecutive reception time intervals. However, it is then necessary to proportionally increase the length of time for which the wake-up signal is transmitted, which entails a higher power consumption by the key, the battery of which can then drain more quickly, and is therefore a significant maintenance drawback for the user. There is therefore a need for a solution that can be used to overcome these drawbacks at least in part.

### SUMMARY OF THE INVENTION

One of the aims of an aspect of the invention is to reduce the power consumption of the electronic control unit. Another aim of an aspect of the invention is to limit the power consumption of the transmission device. Another aim of an aspect of the invention is to ensure that the electronic control unit detects the data of a wake-up signal within a time that is short enough not to affect the function relating to the actuation of the transmission device, such as for example the unlocking of the opening elements.

To this end, an aspect of the invention firstly relates to a method for communicating between a portable transmission device and an electronic control unit of a motor vehicle, said transmission device being configured to transmit signals referred to as “wake-up” signals to said electronic control unit, the electronic control unit being coupled to a receiving antenna and being configured to supply power to said receiving antenna periodically during a time interval referred to as a “reception” time interval in order to be able to receive at least one portion of a wake-up signal transmitted by the transmission device, the duration of a supply period for the receiving antenna being defined as being the length of time between two starting times of two consecutive reception time intervals, the method comprising transmission, by the transmission device, of a plurality of wake-up signals over a plurality of consecutive time intervals referred to as “reference” time intervals, the duration of each reference time interval being equal to the duration of the supply period and each reference time interval being divided into a series of consecutive time slots, at least one wake-up signal of the plurality of wake-up signals being transmitted in each reference time interval, in a time slot that is different from the time slots of the other wake-up signals of the plurality of wake-up signals, and such that the sum of the transmission time intervals of each of the wake-up signals of the plurality of wake-up signals is at least equal to the supply period.

The method according to an aspect of the invention can be used to transmit wake-up signals during multiple reference time intervals according to a predetermined transmission pattern so that all of the time slots are used over all of the reference time intervals, thus making it possible to ensure that at least one portion of a wake-up signal will be received during one of the reception time intervals occurring during the reference time intervals.

Advantageously, the duration of the time slots is identical in order to simplify the transmission pattern used by the transmission device to transmit the wake-up signals during the reference time intervals.

In one embodiment, the length of time for which a wake-up signal is transmitted is less than or equal to 20 ms in order to limit the electrical energy consumption of the transmission device.

Preferably, the length of time for which a wake-up signal is transmitted is of the order of 20 ms, for example when the time slots are of the order of five per reference time interval for a supply period of 100 ms.

Preferably, one or two wake-up signals SR of short duration are transmitted per reference time interval in order to limit the power transmitted by the transmission device over each reference time interval and to be able to render the transmission device easily compliant with the transmission standards in place.

In one embodiment, the duration of the supply period for the receiving antenna is of the order of 100 ms.

Advantageously, the wake-up signals are encoded using a Manchester coding so that the electronic control unit is easily able to detect the wake-up signal and activate the associated function, for example the unlocking of the opening elements of the vehicle.

An aspect of the invention also relates to a computer program product characterized in that it comprises a set of program code instructions that, when executed by one or more processors, configure the one or more processors to carry out a method as presented hereinabove.

An aspect of the invention also relates to a transmission device for a motor vehicle, said vehicle comprising an electronic control unit and a receiving antenna coupled to said electronic control unit, the electronic control unit being configured to supply power to said receiving antenna periodically during a time interval referred to as a “reception” time interval in order to be able to receive at least one portion of a signal referred to as a “wake-up” signal transmitted by the transmission device, the duration of a supply period for the receiving antenna being defined as being the length of time between two starting times of two consecutive reception time intervals, said transmission device being configured to transmit a plurality of wake-up signals to the electronic control unit over a plurality of consecutive time intervals referred to as “reference” time intervals, the duration of each reference time interval being equal to the duration of the supply period and each reference time interval being divided into a series of consecutive time slots, at least one wake-up signal of the plurality of wake-up signals being transmitted in each reference time interval, in a time slot that is different from the time slots of the other wake-up signals of the plurality of wake-up signals, and such that the sum of the transmission time intervals of each of the wake-up signals of the plurality of wake-up signals is at least equal to the supply period.

An aspect of the invention also relates to a communication system comprising a transmission device as presented hereinabove and a motor vehicle, said vehicle comprising an electronic control unit and a receiving antenna coupled to said electronic control unit, the electronic control unit being configured to supply power to said receiving antenna periodically during a time interval referred to as a “reception” time interval in order to be able to receive at least one portion of a signal referred to as a “wake-up” signal transmitted by the transmission device, the duration of a supply period for the receiving antenna being defined as being the length of time between two starting times of two consecutive reception time intervals.

### BRIEF DESCRIPTION OF THE DRAWINGS

Other features and advantages of aspects of the invention will become more clearly apparent on reading the description that follows. This description is purely illustrative and should be read with reference to the appended drawings, in which:

FIG. 1 schematically illustrates one embodiment of the system according to the invention.

FIG. 2 illustrates a first example of a transmission pattern for the wake-up signals according to an aspect of the invention.

FIG. 3 illustrates various examples of transmission patterns for the wake-up signals according to an aspect of the invention.

FIG. 4 illustrates a second example of a transmission pattern for the wake-up signals according to an aspect of the invention.

FIG. 5 illustrates the number of error conditions detected while varying the duration of the period between two reception time intervals using the communication method of the prior art and while using the example of a transmission pattern according to an aspect of the invention from FIG. 4.

### DETAILED DESCRIPTION OF THE PREFERRED EMBODIMENTS

### System

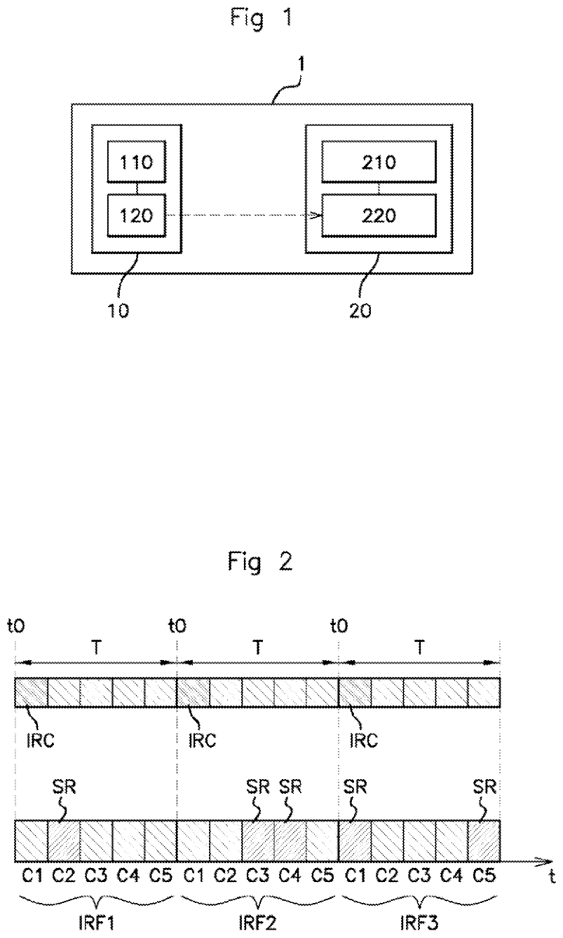

FIG. 1 shows an example of a communication system according to an aspect of the invention. The system 1 comprises a portable transmission device 10 and a motor vehicle 20.

The vehicle 20 comprises an electronic control unit 210 and a receiving antenna 220 coupled to said electronic control unit 210.

The electronic control unit 210 is configured to supply power to the receiving antenna 220 periodically during a time interval referred to as a “reception” time interval IRC, as illustrated in the example in FIG. 2, in order to be able to receive at least one portion of a signal referred to as a “wake-up” signal SR transmitted by the transmission device 10. In particular, the electronic control unit 210 itself can be periodically turned on and then turned off in order to supply the receiving antenna 220 with electricity during the reception time intervals IRC. Thus, the duration of a supply period T for the receiving antenna 220 is defined as being the length of time between two starting times t0 of two consecutive reception time intervals IRC.

The electronic control unit 210 comprises in particular a processor (not shown) that is able to carry out a set of instructions allowing these functions to be provided.

Referring to FIG. 1, the transmission device 10 comprises a control unit 110 (for example of processor or microcontroller type) and a transmission antenna 120.

Referring to FIG. 2, the transmission device 10 is configured to transmit, via said transmission antenna 120, a plurality of wake-up signals SR to the electronic control unit 210 over a plurality of consecutive time intervals referred to as “reference” time intervals IRF1, IRF2, IRF3. Each wake-up signal SR preferably comprises a series of zeros coded using a Manchester coding.

The duration of each reference time interval IRF1, IRF2, IRF3 is equal to the duration of the supply period T and each reference time interval IRF1, IRF2, IRF3 is divided into a series of consecutive time slots. In the example illustrated in FIG. 2, each reference time interval is divided into five consecutive time slots C1, C2, C3, C4, C5. Such division can be used to produce time-division multiplexing for transmitting the wake-up signals SR.

The plurality of wake-up signals SR are transmitted over a plurality of consecutive reference time intervals IRF1, IRF2, IRF3 according to a predetermined transmission pattern, examples of which are provided in FIGS. 2 to 4.

In each transmission pattern according to an aspect of the invention, at least one wake-up signal SR is transmitted in each reference time interval IRF1, IRF2, IRF3 and each wake-up signal SR is transmitted in a different time slot C1, C2, C3, C4, C5 from the time slots of the other wake-up signals SR transmitted according to the predetermined transmission pattern.

Still in the transmission pattern according to an aspect of the invention, the sum of the transmission time intervals of each of the wake-up signals SR of the transmission pattern is at least equal to the supply period T in order to ensure that at least one portion of a transmitted wake-up signal SR will be received by the receiving antenna 220 during a reception time interval IRC concurrent with one of the consecutive reference time intervals IRF1, IRF2, IRF3.

The control unit 110 of the transmission device 10 is able to carry out a set of instructions allowing these functions to be provided, in particular the predetermined transmission pattern to be stored and implemented.

Implementation

The invention will now be described in an embodiment with reference to FIGS. 2 to 5.

The transmission device 10 can advantageously allow the opening elements of the vehicle 20 to be unlocked, but it goes without saying that an aspect of the invention applies to any function of a vehicle 20 that can be carried out remotely from a transmission device 10.

In the example that will be described below, the transmission device 10 transmits multiple signals at predefined moments according to the example of a predetermined transmission pattern in FIG. 2.

First of all, when the user of the transmission device 10 presses the button for unlocking the opening elements, the transmission device 10 triggers the transmission of multiple wake-up signals SR during one or more time slots C1, C2, C3, C4, C5 of each reference time interval IRF1, IRF2, IRF3 according to the predetermined transmission pattern.

Thus, in the example in FIG. 2, the receiving antenna 220 is activated by the electronic control unit 210 during a reception time interval IRC starting at a starting time t0 that coincides with the starting time of the first reference time interval IRF1. In this example, the reception time interval IRC has a duration identical to the duration of a time slot C1, C2, C3, C4, C5, without this limiting the scope of the present invention. Indeed, in another example, the duration of the reception time interval IRC could be less than or greater than the duration of a time slot C1, C2, C3, C4, C5.

In this transmission pattern, no wake-up signal SR is transmitted by the transmission device 10 during the first time slot C1 of the first reference time interval IRF1. The electronic control unit 210 therefore does not receive the data included in the wake-up signals SR at this stage. The transmission device 10 then transmits a wake-up signal SR during the second time slot C2 of the first reference time interval IRF1, but the receiving antenna 220, which is no longer supplied with power during the time slots C2, C3, C4, C5, does not allow this wake-up signal SR to be received.

At the end of the first reference time interval IRF1, as a supply period T has elapsed, the receiving antenna 220 is then reactivated by the electronic control unit 210 during a reception time interval IRC starting at a starting time t0 that coincides with the starting time of the second reference time interval IRF2.

In this transmission pattern, no wake-up signal SR is transmitted by the transmission device 10 during the first time slot C1 and the second time slot C2 of the second reference time interval IRF2. The electronic control unit 210 therefore does not receive the data included in the wake-up signals SR at this stage. The transmission device 10 then transmits a wake-up signal SR during the third time slot C3 of the second reference time interval IRF2 and another wake-up signal SR during the fourth time slot C4 of the second reference time interval IRF2, but the receiving antenna 220, which is no longer supplied with power during the time slots C2, C3, C4, C5, does not allow this wake-up signal SR to be received.

At the end of the second reference time interval IRF2, as a second supply period T has elapsed, the receiving antenna 220 is then reactivated by the electronic control unit 210 during a reception time interval IRC starting at a starting time t0 that coincides with the starting time of the third reference time interval IRF3.

In this transmission pattern, the transmission device 10 transmits a wake-up signal SR during the first time slot C1 of the third reference time interval IRF3. The electronic control unit 210 therefore receives the data included in the wake-up signal SR during the first time slot C1 of the third reference time interval IRF3. The transmission device 10 then transmits a wake-up signal SR during the fifth time slot C5 of the third reference time interval IRF3 so that a wake-up signal SR has been sent during each of the five time slots C1, C2, C3, C4, C5, over different consecutive reference time intervals IRF1, IRF2, IRF3.

Thus, whatever the starting time t0 of the reception time interval IRC, a reception time interval IRC will necessarily coincide with the transmission, and therefore the reception (the time of flight of the signal not being significant vis-a-vis the duration of the wake-up signal and the duration of the reception time interval IRC), of one of the five wake-up signals SR transmitted over the three consecutive reference time intervals IRC1, IRC2, IRC3, since a wake-up signal SR is sent over one of each of the five time slots C1, C2, C3, C4, C5 repeated during the three consecutive reference time intervals IRC1, IRC2, IRC3.

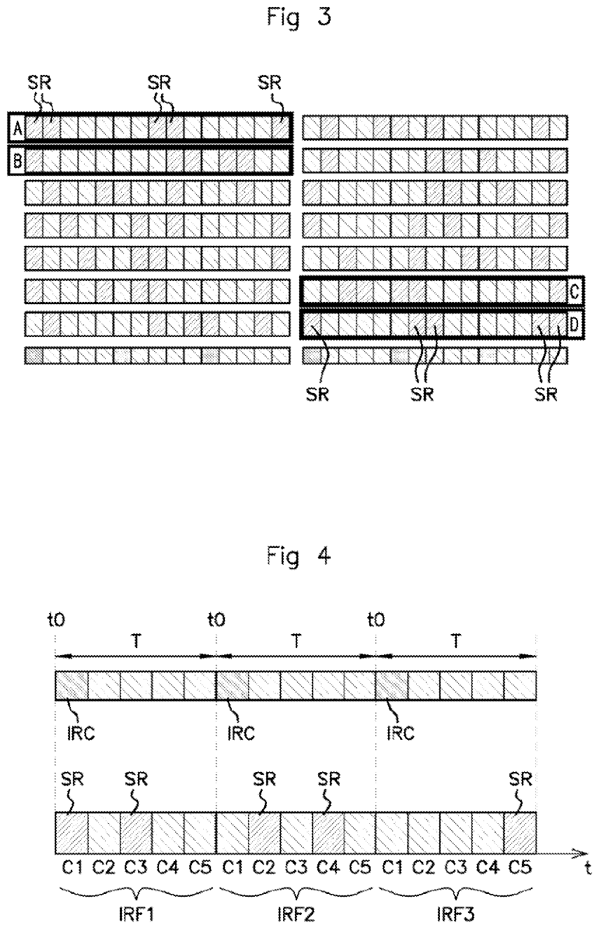

Various examples of transmission patterns for series of three reference time intervals IRF1, IRF2, IRF3, each comprising five time slots C1, C2, C3, C4, C5, have been shown in FIG. 3. However, it should be noted that any other suitable transmission pattern configuration could be used, in particular for a different number of time slots C1, C2, C3, C4, C5 greater than or equal to two or for a different number of reference time intervals IRF1, IRF2, IRF3 greater than or equal to two.

Preferably, the sum of the lengths of time for which the wake-up signals SR are transmitted is less than or equal to the length of time for which a wake-up signal of the prior art is transmitted, for example 40 ms, so as not to increase the electrical energy consumption of the transmission device 10 while ensuring that the wake-up signal SR will be received by the receiving antenna over one of the reference time intervals IRF1, IRF2, IRF3.

The subdivision and spreading of the wake-up signals SR over multiplexed time slots C1, C2, C3, C4, C5 can therefore advantageously be used to significantly extend the supply period T for the receiving antenna 220, that is to say the length of time between two reception time intervals IRC. The subdivision and spreading of the wake-up signals SR over multiplexed time slots C1, C2, C3, C4, C5 can also advantageously be used to limit the transmissions by the transmission device 10 over time, in particular over each reference time interval IRF1, IRF2, IRF3, and therefore to comply with the standards in place. For example, the FCC standard limits the transmission power of a signal to 1 mA every 100 ms. The method according to an aspect of the invention can therefore be used to easily overcome this constraint by limiting the transmission by the transmission device 10 to one or two wake-up signals SR of short duration per reference time interval IRF1, IRF2, IRF3 of 100 ms duration. In the examples provided, the duration of each signal SR is 20 ms and the duration of the reference interval is 100 ms, five wake-up signals SR therefore being necessary in order to cover the duration of a reference interval IRF1, IRF2, IRF3 by being distributed over three consecutive reference intervals IRF1, IRF2, IRF3.

However, it may be advantageous to group the wake-up signals SR, for example in twos, so as to improve the reception of said wake-up signals SR by the receiving antenna 220. This is because the concatenation of the transmission of multiple wake-up signals can be used to ensure correct reception of at least some of the wake-up signals when the reception time interval IRC begins at the end of a time slot during which a wake-up signal SR is transmitted and ends at the beginning of the next time slot. By way of example, in the examples of transmission patterns in FIG. 3, the reference transmission patterns A, B, C and D are particularly advantageous, at least four of the time slots being grouped in twos.

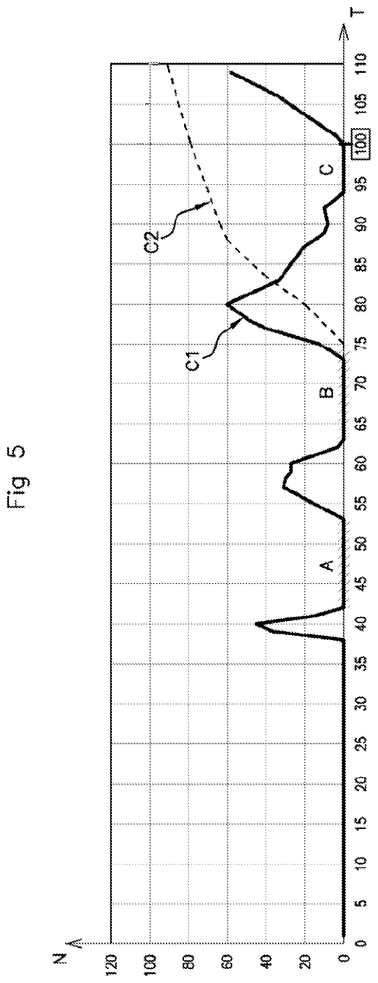

An example of a transmission pattern for which a test by the method according to an aspect of the invention has been performed by varying the period T has been shown in FIG. 4, the results of this test being illustrated by the curve C1 in FIG. 5 and being compared with the results according to the communication method of the prior art, which are themselves illustrated by the dashed curve C2. It can be seen in particular that the period T (x-axis) can be increased to certain values without an error condition (number of error conditions N on the y-axis), that is to say by checking that a sufficient number of data of the wake-up signal SR is received to actuate the function, for example the unlocking of the opening elements of the vehicle 1. This test reveals for example that the period T can be increased to 100 ms using the communication method according to an aspect of the invention without an error condition (curve C1), which was not possible using the communication method of the prior art (curve C2), as this method caused between 90 and 100 error conditions, and which can be used to reduce the electrical energy consumption of the electronic control unit 210 from 390 μA for a period T of 40 ms to 150 μA for a period T of 100 ms, or a 62% consumption gain compared with the prior art.

1. A method for communicating between a portable transmission device and an electronic control unit of a motor vehicle, said transmission device being configured to transmit signals referred to as “wake-up” signals to said electronic control unit, the electronic control unit being coupled to a receiving antenna and being configured to supply power to said receiving antenna periodically during a time interval referred to as a “reception” time interval in order to be able to receive at least one portion of a wake-up signal transmitted by the transmission device, the duration of a supply period for the receiving antenna being defined as being the length of time between two starting times of two consecutive reception time intervals, the method comprising transmission, by the transmission device, of a plurality of wake-up signals over a plurality of consecutive time intervals referred to as “reference” time intervals, the duration of each reference time interval being equal to the duration of the supply period and each reference time interval being divided into a series of consecutive time slots, at least one wake-up signal of the plurality of wake-up signals being transmitted in each reference time interval, in a time slot that is different from the time slots of the other wake-up signals of the plurality of wake-up signals, and such that the sum of the transmission time intervals of each of the wake-up signals of the plurality of wake-up signals is at least equal to the supply period.

2. The method as claimed in claim 1, wherein the duration of the time slots is identical.

3. The method as claimed in claim 1, wherein the length of time for which a wake-up signal is transmitted is less than or equal to 20 ms.

4. The method as claimed in claim 1, wherein one or two wake-up signals are transmitted per reference time interval.

5. The method as claimed in claim 1, wherein the duration of the supply period for the receiving antenna is of the order of 100 ms.

6. The method as claimed in claim 2, wherein the length of time for which a wake-up signal is transmitted is less than or equal to 20 ms.

7. The method as claimed in claim 1, wherein the wake-up signals are encoded using a Manchester coding.

8. A computer program product, comprising a set of program code instructions that, when executed by one or more processors, configure the one or more processors to carry out a method as claimed in claim 1.

9. A transmission device for a motor vehicle, said vehicle comprising an electronic control unit and a receiving antenna coupled to said electronic control unit, the electronic control unit being configured to supply power to said receiving antenna periodically during a time interval referred to as a “reception” time interval in order to be able to receive at least one portion of a signal referred to as a “wake-up” signal transmitted by the transmission device, the duration of a supply period for the receiving antenna being defined as being the length of time between two starting times of two consecutive reception time intervals, said transmission device being configured to transmit a plurality of wake-up signals to the electronic control unit over a plurality of consecutive time intervals referred to as “reference” time intervals, the duration of each reference time interval being equal to the duration of the supply period and each reference time interval being divided into a series of consecutive time slots, at least one wake-up signal of the plurality of wake-up signals being transmitted in each reference time interval, in a time slot that is different from the time slots of the other wake-up signals of the plurality of wake-up signals, and such that the sum of the transmission time intervals of each of the wake-up signals of the plurality of wake-up signals is at least equal to the supply period.

10. A communication system comprising a transmission device as claimed in claim 9 and a motor vehicle, said vehicle comprising an electronic control unit and a receiving antenna coupled to said electronic control unit, the electronic control unit being configured to supply power to said receiving antenna periodically during a time interval referred to as a “reception” time interval in order to be able to receive at least one portion of a signal referred to as a “wake-up” signal transmitted by the transmission device, the duration of a supply period for the receiving antenna being defined as being the length of time between two starting times of two consecutive reception time intervals.
